(19) United States
(12) Patent Application Publication
(10) Pub. No.: US 2007/0151597 A1
(43) Pub. Date: Jul. 5, 2007

(54) Nanocrystal and photovoltaic device comprising the same

(75) Inventors: Hsueh-Shih Chen, Hsinchu City (TW); Shu-Ru Chung, Baoshan Township (TW); Gwo-Yang Chang, Sansia Township (TW); Shih-Jung Tsai, Hsinchu City (TW)

Correspondence Address: BACON & THOMAS, PLLC, 625 SLATERS LANE, FOURTH FLOOR, ALEXANDRIA, VA, 22314, US

(73) Assignee: Industrial Technology Research Institute, Hsinchu (TW)

(21) Appl. No.: 11/515,031

(22) Filed: Sep. 5, 2006

(30) Foreign Application Priority Data
Dec. 30, 2005 (TW) 094147581

(51) Int. Cl. H01L 31/00

(52) U.S. Cl. 136/256

(57) ABSTRACT

A nanocrystal with high light absorption efficiency and a broad absorption spectrum, and a photovoltaic device comprising the nanocrystal are disclosed. The nanocrystal of the present invention comprises a core, a first shell grown and formed on the surface of the core, and a second shell grown and formed on the surface of the core or the surface of the first shell. Besides, the core, the first shell, and the second shell are a low energy gap material, a middle energy gap material, and a high energy gap material, respectively. Therefore, the nanocrystal has a great absorption in the ultraviolet range, the visible light range, and the infrared range; and the solar spectrum can be converted effectively to improve the light conversion efficiency thereof.

### BACKGROUND OF THE INVENTION

1. Field of the Invention

The present invention relates to nanostructure composed of multiple materials and, more particularly, to a nanocrystal and the application comprising the same.

2. Description of Related Art

Many non-regenerable energy resources, such as fossil-oils and coal are finite in the earth. Therefore, as the consumption of such resources increases annually, the infinite energy resources, such as solar energy, geothermal power, or hydropower, are becoming the focal point of energy development.

Solar cells can convert the inexhaustible solar energy into electrical power in a safe, pollution-free, noiseless, low-priced manner, and no other energy resources are needed. Therefore, environmental pollution and the so-called greenhouse effect can be reduced by using solar cells. In addition, the solar cell has a long operating life-time.

So far, the solar cell uses a silicon semiconductor as its main material. The silicon semiconductor based solar cell has a high photoelectrical conversion efficiency. However, it has the problems of high equipment cost and high manufacturing cost. Even replacing the silicon semiconductor with other semiconductor materials, such as indium gallium nitride (InGaN), the issue of high cost still exists. Hence, the application of solar cells is restricted in specific places, such as the space, remote districts, or exhibitions. Furthermore, the popularity of solar cells among ordinary people is still low.

The organic polymer solar cell with large size has become the research focal point recently because of its simple manufacturing process, low cost, and easy manufacturing. Therefore, the foregoing problems of the silicon conductor based solar cell can be eliminated. Besides, organic polymers can be coated on walls, paper, or clothes to produce the flexible photovoltaic device or stick-page so that the organic polymer solar cell will become a convenient and economical choice to obtain energy.

Unfortunately, the mobility of organic conjugated polymer (<10⁻⁴ cm²V⁻¹s⁻¹) is lower than that of the silicon semiconductor (>10³ cm²V⁻¹s⁻¹). As a result, the photoelectrical conversion efficiency of organic polymer solar cell is generally a low value. The well-known improved method is to blend the electron-transport material, such as conjugated small molecule, into the organic polymer. Although the improved method can enhance the photoelectrical conversion efficiency of solar cell, the jump velocity of a carrier between small molecules is still slower than that in the silicon semiconductors. Thus, it is difficult to improve effectively the photoelectrical conversion efficiency of the organic polymer solar cell.

In another aspect, the blending of the inorganic nano-particles into the conjugated polymer to produce an organic-inorganic hybrid solar cell has been researched. The carrier transport velocity and photoelectrical transfer of the organic-inorganic hybrid solar cell are improved by introducing the inorganic nano-particles with good electron transfer ability. However, the carrier transport velocity in organic-inorganic hybrid films is still limited to the jump velocity of carriers and photo absorbance efficiency.

In 2002, the Alivisatos research group blended CdSe nanorods (L×W=60 nm×7 nm) with small amounts of conductive polymer to produce a solar cell. Because of the physical property of nanorods themselves, the photo-absorbance, carrier-transport, and photo-transfer efficiency of solar cell comprising CdSe nanorods are improved. However, the CdSe nanocrystal may cause damage to the environment or humans. Besides, the absorption spectrum of CdSe nanocrystal is limited.

Solar energy has long been looked to as a potential energy with a full spectrum range. If the absorption spectrum of the photoactive material of the solar cell matches that of the sun, then the solar energy's conversion efficiency can be effectively enhanced. Therefore, it is desirable to provide a nanocrystal that can absorb wide range of wavelengths including ultraviolet rays, visible light and infrared light to absorb the wavelengths of the whole sunlight, to improve the light transfer efficiency, to enhance the photo-absorbency, and increase the carrier-transport efficiency greatly.

### SUMMARY OF THE INVENTION

The present invention provides a nanocrystal with high light absorption efficiency, and a photovoltaic device using the same. Consequently the photovoltaic device can convert the light energy into the electric energy effectively by using nanocrystals with a broad absorption spectrum.

The present invention provides a nanocrystal, which comprises a core; a first shell grown from the surface of the core; and a second shell grown from the surface of the core or the surface of the first shell. Besides, the core, the first shell, and the second shell have different energy gaps. The core is a low energy gap material having an energy gap that ranges from 1.24 eV to 0.41 eV, the first shell is a middle energy gap material having an energy gap that ranges from 2.48 eV to 1.24 eV, and the second shell is a high energy gap material having an energy gap that ranges from 6.20 eV to 2.48 eV.

Therefore, the range of the absorption spectrum of the nanocrystal is broad so as to effectively absorb the solar spectrum and increase the light conversion efficiency, and the light absorption efficiency and the carrier transfer efficiency thereof are improved.

The low energy gap material, middle energy gap material, or the high energy gap material used in the nanocryatal of the present invention can be any conventional light absorption material. Preferably, the low energy gap material, middle energy gap material, or the high energy gap material is a semiconductor that can absorb light. More preferably, the low energy gap material is a group II-VI semiconductor, the middle energy gap material is a group III-V semiconductor, and the high energy gap material is a group IV semiconductor.

The high energy gap material used in the nanocrystal of the present invention can be any light absorption material having an absorption range from 200 to 500 nm. Preferably, the high energy gap material is at least one compound selected from a group consisting of MgS, MgSe, MgTe, MnS, MnSe, MnTe, ZnS, ZnSe, GaN, SiC, TiO₂, C derivatives, and an alloy thereof. The middle energy gap material used in the nanocrystal of the present invention can be any light absorption material having an absorption range from 500 to 1000 nm. Preferably, the middle energy gap material is at least one compound selected from a group consisting of ZnTe, CdS, CdSe, CdTe, HgS, HgI₂, PbI₂, InP, GaP, TlBr, C derivatives, and an alloy thereof. The low energy gap material used in the nanocrystal of the present invention can be any light absorption material having absorption range from 1000 to 3000 nm. Preferably, the high energy gap material is at least one compound selected from a group consisting of PbS, PbSe, PbTe, HgSe, HgTe, InAs, InSb, GaSb, Si, Ge, and an alloy thereof.

In addition, the low energy gap material, the middle energy gap material, or the high energy gap material contained in the nanocrystal of the present invention can be an inorganic light absorption material. Preferably, the inorganic light absorption material is at least one compound selected from a group consisting of PbS, PbSe, and TiO₂.

The shape of the nanocrystal of the present invention is not limited. Preferably, the shape of the nanocrystal is a rod, a tetrapod, a radial form, an arrow, a teardrop, an irregular form, or a combination thereof. Moreover, the structure of the nanocrystal's core is not limited but preferably the core is a quantum dot.

In one preferable embodiment, the core of the nanocrystal of the present invention is a quantum dot composed of ZnSe, ZnSe/ZnS, ZnSe/ZnSeS, ZnS, or ZnTe. In another preferable embodiment, the nanocrystal of the present invention comprises a core containing ZnSe, ZnTe, or ZnS, a first shell containing CdSe, and a second shell containing PbSe.

In addition, the present invention provides a photovoltaic device, which comprises a top substrate having a first electrode thereon, a bottom substrate having a second electrode thereon, and a photoactive layer disposed between the first electrode and the second electrode, wherein the photoactive layer comprises plural nanocrystals, and a conductive material.

The nanocryatal comprises a core, a first shell grown from the surface of the core, and a second shell grown from the surface of the core or the surface of the first shell. Besides, the core, the first shell, and the second shell are a low energy gap material, a middle energy gap material, and a high energy gap material, respectively. All of them have different energy gaps.

In fact, the low energy gap material has an energy gap that ranges from 1.24 eV to 0.41 eV; the first shell has an energy gap that ranges from 2.48 eV to 1.24 eV, and the second shell has an energy gap that ranges from 6.20 eV to 2.48 eV.

Therefore, the light absorption efficiency, the carrier transfer efficiency, and the light conversion efficiency of the photovoltaic device of the present invention can be significantly improved. Besides, the manufacturing process of the photovoltaic device with large size is simplified, and the cost of the same is reduced. Moreover, the photovoltaic device with large size is suitable to be manufactured on a mass production scale.

The conductive material used in the photovoltaic device of the present invention can be any conventional conductive material. Preferably, the conductive material is an organic conductive material, an inorganic conductive material, or a combination thereof. More preferably, the conductive material is Poly(3-hexyl thiophene)(P3HT), N,N′-di(naphthalen)-N,N′-diphenyl-benzidine(NPB), N,N′-bis(naphthalen-1-yl)-N,N′-bis(phenyl)benzidine(α-NPB), N,N′-di(naphthalene-1-yl)N,N′-diphenyl-9,9,-dimethyl-fluorene(DMFL-NPB), N,N′-di(naphthalene-1-yl)-N,N′-diphenyl-spiro(Spiro-NPB), N,N′-Bis-(3-methylphenyl)-N,N′-bis-(phenyl)-benzidine (TPD), N,N′-bis-(3-methylphenyl)-N,N′-bis-(phenyl)-spiro (Spiro-TPD), N,N′-bis-(3-methylphenyl)-N,N′-bis-(phenyl)-9,9-diphenyl-fluorene(DMFL-TPD), 1,3-bis(carbazol-9-yl)-benzene(MCP), 1,3,5-tris(carbazol-9-yl)-benzene(TCP), N,N,N′,N′-tetrakis(naphth-1-yl)-benzidine(TNB), poly(N-vinyl carbazole)(PVK), poly(2-methoxy-5-(2′-ethylhexyloxy)-1,4-phenylenevinylene)(MEH-PPV), poly[2-Methoxy-5-(2′-ethylhexyloxy)-1,4-phenylenevinylene-co-4,4′-bisphenylenevinylene](MEH-BP-PPV), poly[(9,9-dioctylfluoren-2,7-diyl)-co-(1,4-diphenylene-vinylene-2-methoxy-5-{2-ethylhexyloxy}benzene)](PF-BV-ME), poly[(9,9-dioctylfluoren-2,7-diyl)-co-(2,5-dimethoxy benzen-1,4-diyl)](PF-DMOP), poly[(9,9-dihexylfluoren-2,7-diyl)-alt-co-(benzen-1,4-diyl)](PFH), poly[(9,9-dihexylfluoren-2,7-diyl)-co-(9-ethylcarbazol-2,7-diyl)](PFH-EC), poly[(9,9-dihexylfluoren-2,7-diyl)-alt-co-(2-methoxy-5-{2-ethylhexyloxy}phenylen-1,4-diyl)](PFH-MEH), poly[(9,9-dioctylfluoren-2,7-diyl)(PFO), poly[(9,9-di-n-octylfluoren-2,7-diyl)-co-(1,4-vinylenephenylene)](PF-PPV), poly[(9,9-dihexylfluoren-2,7-diyl)-alt-co-(benzen-1,4-diyl)](PF-PH), poly[(9,9-dihexylfluoren-2,7-diyl)-alt-co-(9,9′-spirobifluoren-2,7-diyl)](PF-SP), poly(N,N′-bis(4-butylphenyl)-N,N′-bis(phenyl)benzidine(poly-TPD), poly(N,N′-bis(4-butylphenyl)-N,N′-bis(phenyl) benzidine(poly-TPD-POSS), poly[(9,9-dihexylfluoren-2,7-diyl)-co-(N,N′-di(4-butylphenyl)-N,N′-diphenyl-4,4′-diyl-1,4-diamino benzene)](TAB-PFH), N,N′-pis(phenanthren-9-yl)-N,N′-diphenylbenzidine(PPB), tris-(8-hydroxy quinoline)-aluminum(Alq3), bis-(2-methyl-8-quinolinolate)-4-(phenylphenolato)-aluminium(BAlq3), 2,9-dimethyl-4,7-diphenyl-1,10-phenanthroline(BCP), 4,4′-bis(carbazol-9-yl) biphenyl(CBP), 3-(4-Biphenylyl)-4-phenyl-5-tert-butylphenyl-1,2,4-triazole(TAZ), MEH-PPV, MEH-BP-PPV, PF, PF-BV-MEH, PF-DMOP, PFH, PFH-EC, PFH-MEH, PFO, PFOB, PF-PPV, PF-PH, PF-SP, poly-TPD, poly-TPD-POSS, TAB-PFH, PPB, or a combination thereof. Among them, Poly(3-hexylthiophene), MEH-PPV, MDMO-PPV or a combination thereof is preferred.

The photoactive layer is electrically connected to the first electrode and the second electrode. Therefore, as the photoactive layer absorbs solar energy, a voltage drop is formed because the free electrons or electron/hole pairs generated in the photoactive layer are separated and conducted to the electrodes. Then, a direct current is therefore generated and transferred by the electrodes electrically connecting to the photoactive layer.

Furthermore, the top substrate or the bottom substrate of the photovoltaic device of the present invention can comprise a carrier transfer layer to improve the carrier transfer efficiency. The carrier transfer layer is used to transfer the carriers generated in the photoactive layer to the electrodes disposed on the top substrate and the bottom substrate. In the present invention, the carrier transfer layer can be any conventional carrier transferring material. Preferably, the carrier transfer layer is Poly(3,4-ethylene dioxythiophene)(PEDOT), poly(styrenesulfonate)(PSS), or a combination thereof.

In the photovoltaic device of the present invention, the arrangement of the nanocrystals dispersed in the conductive material is not limited. Preferably, the nanocrystals are dispersed randomly, uniformly, or in the manner of concentration gradient in the conductive material. Besides, the weight ratio of the nanocrystal and the conductive material contained in the photoactive layer is not limited. Preferably, the photoactive layer comprises the nanocrystals in an amount of 70% to 90% by weight, and the conductive material in an amount of 10% to 30% by weight.

Because the photoactive layer is a hybrid of organic conductive material and an inorganic nanocrystal, it can be coated on a surface of any material, and the application thereof is not limited. In one preferred embodiment of the present invention, the top substrate and the bottom substrate are flexible, and applied to a solar cell in the form of a patch.

Compared with the conventional silicon semiconductor based photovoltaic device, the manufacturing process of the photovoltaic device of the present invention is simplified, the cost of it is reduced, and it is suitable to manufacture the photovoltaic device with large size on a mass production basis. In addition, the light absorption efficiency, the carrier transfer efficiency, and the light conversion efficiency of the photovoltaic device of the present invention can be significantly improved relative to the prior art.

Other objects, advantages, and novel features of the invention will become more apparent from the following detailed description when taken in conjunction with the accompanying drawings.

### BRIEF DESCRIPTION OF THE DRAWINGS

FIGS. 1a to 1c show a schematic diagram of a nanocrystal according to a preferred embodiment of the present invention;

FIGS. 2a to 2c are transmission electron micrographs (TEM) of the nanocrystal according to a preferred embodiment of the present invention;

FIG. 3 is a schematic diagram of a photovoltaic device according to a preferred embodiment of the present invention;

FIG. 4 is a schematic diagram of a photovoltaic device according to another preferred embodiment of the present invention; and

FIG. 5 is a schematic diagram of a photovoltaic device according to yet another preferred embodiment of the present invention.

### DETAILED DESCRIPTION OF THE PREFERRED EMBODIMENT

### Embodiment 1

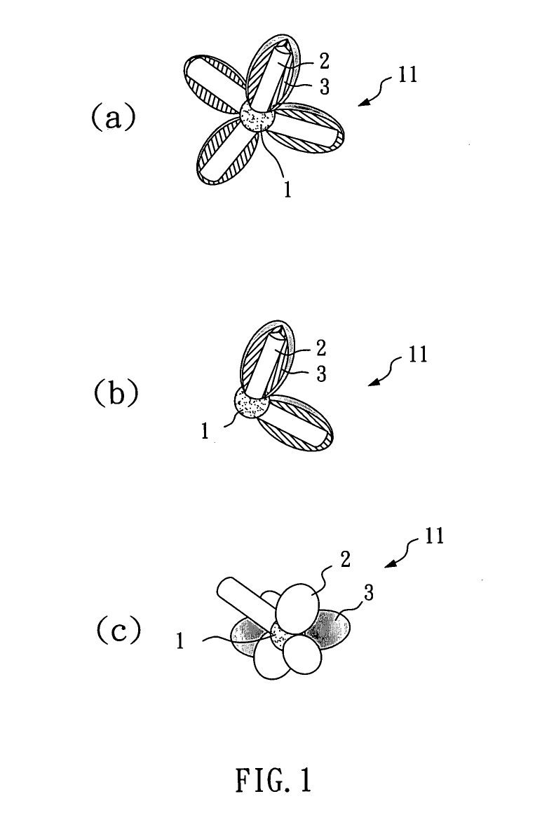

With reference to FIGS. 1a to 1c, schematic diagrams of a nanocrystal according to the preferred embodiments of the present invention are illustrated. As shown in FIGS. 1a to 1c, the nanocrystal comprises a core 1, a first shell 2, and a second shell 3. In this embodiment, the core 1 is composed of ZnSe semiconductor with a structure of a quantum dot, the first shell 2 is composed of a CdSe semiconductor, and the second shell 3 is composed of a PbSe inorganic material. Therefore, the nanocrystal 11 of this embodiment includes three materials with different absorption wavelengths. The wavelength of the absorption light of the ZnSe semiconductor is in the range of ultraviolet. The wavelength of the absorption light of the CdSe semiconductor is in the range of visible light. The wavelength of the absorption light of the PbSe inorganic material is in the range of infrared light.

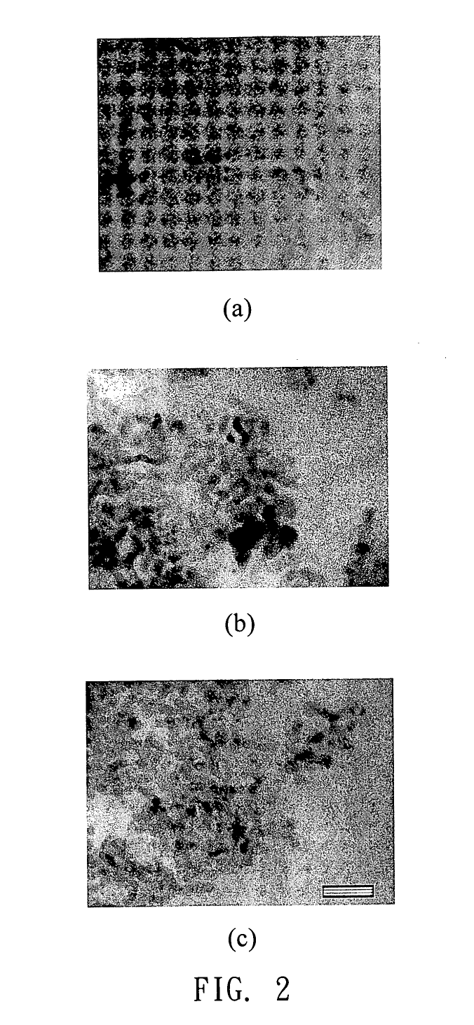

As shown in FIG. 1a, the shape of the nanocrystal 11 is a tetrapod. The first shell is grown and formed on the surface of the core 1. The second shell is grown and formed on the surface of the first shell. From the transmission electron micrograph (TEM) shown in FIG. 2a, the nanocrystal of this embodiment is confirmed to have the shape of a tetrapod.

As shown in FIG. 1b, the shape of the nanocrystal 11 is a rod. The first shell is grown and formed on the surface of the core 1. The second shell is grown and formed on the surface of the first shell. From the transmission electron micrograph (TEM) shown in FIG. 2b, the nanocrystal of this embodiment is confirmed to have the shape of a rod.

As shown in FIG. 1c, the shape of the nanocrystal 11 is a radial form. The first shell is grown and formed on the surface of the core 1. The second shell is grown and formed on the surface of the first shell. From the transmission electron micrograph (TEM) shown in FIG. 2c, the nanocrystal of this embodiment is confirmed to have the radial shape.

In this embodiment, the nanocrystal is prepared by providing a core of ZnSe, first. Then, a second precursor solution and a third precursor solution are applied to react with the core to form the first shell and the second shell. The detailed steps for preparing nanocrystal of this embodiment are described as follow:

First, 1 mmol of selenium (Se) powder is dried in a vacuum to remove moisture. Then, the dried selenium powders, 2 ml of tri-n-octylphosphine (TOP), and 2 ml of toluene are mixed and dispersed by supersonic vibration for 30 minutes under an inert atmosphere to form a TOPSe solution. In this embodiment, the TOPSe solution is a colorless liquid. Besides, the tri-n-octylphosphine used in the steps for preparing nanocrystal of this embodiment can be replaced by tributylphosphine (TBP).

In another aspect, 1 mmole of zinc oxide powder is added in a three-neck bottle, and is heated to 120° C. under an inert atmosphere to remove moisture. After cooling to room temperature, 40 mmol of benzoic acid (stearic acid) and 20 mmol of tri-n-octylphosphine oxide (TOPO) are added to the three-neck bottle to form a mixture. The mixture is then heated to 150° C. and maintained for 20 minutes to form a transparent liquid. Subsequently, the transparent liquid is heated to 300° C. After the temperature of the transparent liquid has risen to 300° C. through heating, the prepared TOPSe solution is added to the transparent liquid, and keeps reacting for 5 minutes to form a mixture that comprises ZnSe cores.

In addition, the selenium (Se) powder used in the steps for preparing nanocrystal of this embodiment can be replaced by sulfur (S) powder, or tellurium (Te) powder, and the cores composed of ZnS or ZnTe can be therefore obtained by the same preparing steps and reaction conditions.

After the ZnSe cores are formed, the mixture is cooled to 100° C. Then, a precursor solution of the first shell is added into the mixture. The mixture is then heated to 320° C. and maintained at that temperature for 30 minutes. Subsequently, a TOPSSe solution is added into the mixture under an inert atmosphere and keeps reacting for 10 minutes to grow the first shell from the cores. In this embodiment, the material of the first shell is CdSe. The precursor solution of the first shell contains 1 mmol of CdO, 3 mmol of stearic acid, and 3 mmol of TOPO. The TOPSSe solution contains 4 ml of TOP, 1 mmol of sulfur, 1 mmol of selenium, and 2 ml of toluene.

After the first shell is formed, the mixture is cooled to 100° C., and a precursor solution of the second shell is then added into the mixture. Subsequently, the mixture is heated to 280° C. and maintained at that temperature for 30 minutes. Finally, a TOPSe solution is added to the mixture under an inert atmosphere and keeps reacting for 5 to 10 minutes to grow the second shell from the cores and the nanocrystals of this embodiment are obtained. In this embodiment, the material of the second shell is PbSe. The precursor solution of the second shell contains 0.3 mmol of PbO, 1 mmol of stearic acid, and 1 mmol of TOPO. The TOPSe solution contains 1 ml of TOP, 0.2 mmol of selenium, and 2 ml of toluene.

### Embodiment 2

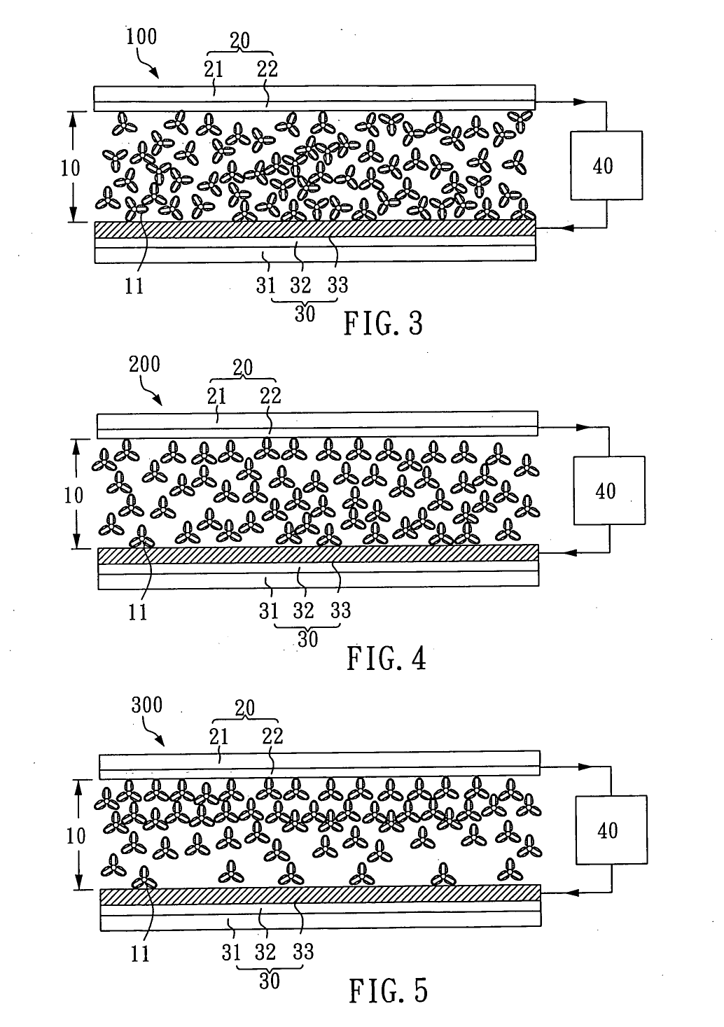

FIGS. 3 to 5 shows photovoltaic devices 100, 200, and 300 according to the preferred embodiments of the present invention. As shown in FIGS. 3 to 5, the photovoltaic devices 100, 200, and 300 mainly comprise a photoactive layer having plural nanocrystals therein, a flexible top substrate 20, and a flexible bottom substrate, wherein the photoactive layer is disposed between the top substrate 20 and the bottom substrate 30.

In this embodiment, the photoactive layer contains 85 wt % of nanocrystals 11, and 15 wt % of Poly(3-hexylthiophene) (P3HT) as the organic conductive material. As shown in FIGS. 3 to 5, the top substrate 20 includes a substrate 21 and a first electrode 22. The bottom substrate 30 includes a substrate 31, a second electrode 32, and a carrier transfer layer 33. In this embodiment, the first electrode is a cathode composed of aluminum, the second electrode is an anode composed of indium-tin oxide, and the material of the carrier transfer layer 33 is a combination of Poly(3,4-ethylene dioxythiophene) and poly(styrenesulfonate). Moreover, the nanocrystal 11 used in this embodiment is tetrapod-shaped nanocrystal according to embodiment 1 of the present invention.

The photovoltaic device 100, 200, or 300 can further connect to a load/device 40 in order to form a current circuit. As shown in FIGS. 3 to 5, as the photovoltaic device 100, 200, or 300 is illuminated by an external light source, free electrons or electron/hole pairs are generated in the photoactive layer, and a resulting current flow in the direction of arrows is then exploited in load/device 40.

In this embodiment, the arrangements of the nanocrystals dispersed in the conductive material of photoactive layer 10 of the photovoltaic devices 100, 200, and 300 are different. As shown in FIGS. 3 to 5, the nanocrystals can be dispersed randomly (FIG. 3), dispersed uniformly (FIG. 4), or dispersed with a concentration gradient (FIG. 5) in the conductive material.

Although the present invention has been explained in relation to its preferred embodiment, it is to be understood that many other possible modifications and variations can be made without departing from the scope of the invention as hereinafter claimed.

What is claimed is:

1. A nanocrystal, comprising:
a core;
a first shell grown from the surface of the core; and
a second shell grown from the surface of the core or the surface of the first shell;
wherein the core is a low energy gap material having an energy gap that ranges from 1.24 eV to 0.41 eV, the first shell is a middle energy gap material having an energy gap that ranges from 2.48 eV to 1.24 eV, and the second shell is a high energy gap material having an energy gap that ranges from 6.20 eV to 2.48 eV.

2. The nanocrystal as claimed in claim 1, wherein the low energy gap material is a group II-VI semiconductor, the middle energy gap material is a group III-V semiconductor, and the high energy gap material is a group IV semiconductor.

3. The nanocrystal as claimed in claim 1, wherein the high energy gap material is at least one compound selected from a group consisting of MgS, MgSe, MgTe, MnS, MnSe, MnTe, ZnS, ZnSe, GaN, SiC, TiO₂, C derivatives, and an alloy thereof.

4. The nanocrystal as claimed in claim 1, wherein the middle energy gap material is at least one compound selected from a group consisting of ZnTe, CdS, CdSe, CdTe, HgS, HgI₂, PbI₂, InP, GaP, TlBr, C derivatives, and an alloy thereof.

5. The nanocrystal as claimed in claim 1, wherein the low energy gap material is at least one compound selected from a group consisting of PbS, PbSe, PbTe, HgSe, HgTe, InAs, InSb, GaSb, Si, Ge, and an alloy thereof.

6. The nanocrystal as claimed in claim 1, wherein the low energy gap material, the middle energy gap material, or the high energy gap material is an inorganic light absorption material.

7. The nanocrystal as claimed in claim 3, wherein the inorganic light absorption material is at least one compound selected from a group consisting of PbS, PbSe, and TiO₂.

8. The nanocrystal as claimed in claim 1, wherein the shape of the nanocrystal is a rod, a tetrapod, a radial form, an arrow, a teardrop, an irregular form, or a combination thereof.

9. The nanocrystal as claimed in claim 8, wherein the shape of the nanocrystal is a rod, a tetrapod, a radial form, or a combination thereof.

10. The nanocrystal as claimed in claim 1, wherein the core is a quantum dot.

11. The nanocrystal as claimed in claim 10, wherein the core comprises ZnSe, ZnSe/ZnS, ZnSe/ZnSeS, ZnS, or ZnTe.

12. The nanocrystal as claimed in claim 1, wherein the core comprises ZnSe, ZnS, or ZnTe.

13. The nanocrystal as claimed in claim 1, wherein the first shell comprises CdSe.

14. The nanocrystal as claimed in claim 1, wherein the second shell comprises PbSe.

15. The nanocrystal as claimed in claim 1, wherein the core comprises ZnSe, or ZnTe, the first cell comprises CdSe, and the second shell comprises PbSe.

16. A photovoltaic device, comprising:
a top substrate having a first electrode thereon;
a bottom substrate having a second electrode thereon; and
a photoactive layer disposed between the first electrode and the second electrode, and the photoactive layer comprises plural nanocrystals, and a conductive material;
wherein the nanocrystal comprises a core, a first shell grown from the surface of the core, and a second shell grown from the surface of the core or the surface of the first shell; and wherein the core is a low energy gap material having an energy gap that ranges from 1.24 eV to 0.41 eV, the first shell is a middle energy gap material having an energy gap that ranges from 2.48 eV to 1.24 eV, and the second shell is a high energy gap material having an energy gap that ranges from 6.20 eV to 2.48 eV.

17. The photovoltaic device as claimed in claim 16, wherein the conductive material comprises an organic conductive material, an inorganic conductive material, or a combination thereof.

18. The photovoltaic device as claimed in claim 16 wherein the conductive material is at least one compound selected from a group consisting of N,N′-di(naphthalen)-N,N′-diphenyl-benzidine(NPB), N,N′-bis(naphthalen-1-yl)-N,N′-bis(phenyl)benzidine(α-NPB), N,N′-di(naphthalene-1-yl)N,N′-diphenyl-9,9,-dimethyl-fluorene(DMFL-NPB), N,N′-di(naphthalene-1-yl)-N,N′-diphenyl-spiro(Spiro-NPB), N,N′-Bis-(3-methylphenyl)-N,N′-bis-(phenyl)-benzidine (TPD), N,N′-bis-(3-methylphenyl)-N,N′-bis-(phenyl)-spiro (Spiro-TPD), N,N′-bis-(3-methylphenyl)-N,N′-bis-(phenyl)-9,9-diphenyl-fluorene(DMFL-TPD), 1,3-bis(carbazol-9-yl)-benzene(MCP), 1,3,5-tris(carbazol-9-yl)-benzene(TCP), N,N,N′,N′-tetrakis(naphth-1-yl)-benzidine(TNB), poly(N-vinyl carbazole) (PVK), poly(2-methoxy-5-(2′-ethylhexyloxy)-1,4-phenylenevinylene)(MEH-PPV), poly[2-Methoxy-5-(2′-ethylhexyloxy)-1,4-phenylenevinylene-co-4,4′-bisphenylenevinylene](MEH-BP-PPV), poly[(9,9-dioctylfluoren-2,7-diyl)-co-(1,4-diphenylene-vinylene-2-methoxy-5-{2-ethylhexyloxy}benzene)](PF-BV-ME), poly[(9,9-dioctylfluoren-2,7-diyl)-co-(2,5-dimethoxy benzen-1,4-diyl)](PF-DMOP), poly[(9,9-dihexylfluoren-2,7-diyl)-alt-co-(benzen-1,4-diyl)](PFH), poly[(9,9-dihexylfluoren-2,7-diyl)-co-(9-ethylcarbazol-2,7-diyl)](PFH-EC), poly[(9,9-dihexylfluoren-2,7-diyl)-alt-co-(2-methoxy-5-{2-ethylhexyloxy}phenylen-1,4-diyl)](PFH-MEH), poly[(9,9-dioctylfluoren-2,7-diyl)(PFO), poly[(9,9-di-n-octylfluoren-2,7-diyl)-co-(1,4-vinylenephenylene)](PF-PPV), poly[(9,9-dihexylfluoren-2,7-diyl)-alt-co-(benzen-1,4-diyl)](PF-PH), poly[(9,9-dihexylfluoren-2,7-diyl)-alt-co-(9,9′-spirobifluoren-2,7-diyl)](PF-SP), poly(N,N′-bis(4-butylphenyl)-N,N′-bis(phenyl)benzidine(poly-TPD) poly(N,N′-bis(4-butylphenyl)-N,N′-bis(phenyl) benzidine(poly-TPD-POSS), poly[(9,9-dihexylfluoren-2,7-diyl)-co-(N,N′-di(4-butylphenyl)-N,N′-diphenyl-4,4′-diyl-1,4-diamino benzene)](TAB-PFH), N,N′-pis(phenanthren-9-yl)-N,N′-diphenylbenzidine(PPB), tris-(8-hydroxy quinoline)-aluminum(Alq3), bis-(2-methyl-8-quinolinolate)-4-(phenylphenolato)-aluminium(BAlq3), 2,9-dimethyl-4,7-diphenyl-1,10-phenanthroline(BCP), 4,4′-bis(carbazol-9-yl) biphenyl(CBP), 3-(4-Biphenylyl)-4-phenyl-5-tert-butylphenyl-1,2,4-triazole(TAZ), MEH-PPV, MEH-BP-PPV, PF, PF-BV-MEH, PF-DMOP, PFH, PFH-EC, PFH-MEH, PFO, PFOB, PF-PPV, PF-PH, PF-SP, poly-TPD, poly-TPD-POSS, TAB-PFH, and PPB.

19. The photovoltaic device as claimed in claim 16, wherein the photoactive layer is electrically connected to the first electrode and the second electrode.

20. The photovoltaic device as claimed in claim 16, wherein the top substrate or the bottom substrate further comprises a carrier transfer layer.

21. The photovoltaic device as claimed in claim 16, wherein the nanocrystals are randomly dispersed in the conductive material.

22. The photovoltaic device as claimed in claim 16, wherein the nanocrystals are uniformly dispersed in the conductive material.

23. The photovoltaic device as claimed in claim 16, wherein the nanocrystals are dispersed in the conductive material in the manner of concentration gradient.

24. The photovoltaic device as claimed in claim 16, wherein the photoactive layer comprises the nanocrystals in an amount of 70% to 90% by weight, and the conductive material in an amount of 10% to 30% by weight.

25. The photovoltaic device as claimed in claim 16, wherein the core, the first shell, or the second shell is an inorganic light-absorption material composed of PbS, PbSe, TiO₂, or a combination thereof.

26. The photovoltaic device as claimed in claim 16, wherein the low energy gap material is a group II-VI semiconductor, the middle energy gap material is a group III-V semiconductor, and the high energy gap material is a group IV semiconductor.

27. The photovoltaic device as claimed in claim 16, wherein the shape of nanocrystal is a tetrapod.

28. The photovoltaic device as claimed in claim 16, wherein the core is a quantum dot.

29. The photovoltaic device as claimed in claim 16, wherein the core comprises ZnSe, or ZnTe, the first cell comprises CdSe, and the second shell comprises PbSe.

30. The photovoltaic device as claimed in claim 16, wherein at least one of the top substrate and the bottom substrate is a flexible substrate.
